(19) United States
(12) Patent Application Publication
(10) Pub. No.: US 2024/0274395 A1
(43) Pub. Date: Aug. 15, 2024

(54) CHARGED PARTICLE BEAM DEVICE AND METHOD FOR DEMAGNETIZING MAGNETIC LENS

(71) Applicant: Hitachi High-Tech Corporatiom, Minato-ku, Tokyo (JP)

(72) Inventors: Shingo HAYASHI, Tokyo (JP); Hideyuki KAZUMI, Tokyo (JP); Zhaohui CHENG, Tokyo (JP)

(21) Appl. No.: 18/567,920

(22) PCT Filed: Jun. 22, 2021
(86) PCT No.: PCT/JP2021/023618

§ 371 Date: Dec. 7, 2023

(51) Int. Cl. H01J 37/141; H01J 37/28

(52) U.S. Cl. CPC H01J 37/141; H01J 37/28; H01J 2237/1415

(57) ABSTRACT

In order to demagnetize the magnetic lens, an alternating attenuation current is applied as an excitation current, the alternating attenuation current oscillating such that a current value alternately becomes a first-polarity current I₁(n) and a second-polarity current I₂(n) in which n represents the number of times of amplitude variation. The first-polarity current I₁(n) and the second-polarity current I₂(n) are expressed as I₁(n)=A×α₁(n), I₂(n)=−A×β×α₂(n), in which oscillation of the alternating attenuation current is started from a first polarity, A represents an amplitude of the first-polarity current, β represents an asymmetric coefficient, α₁(n) represents an attenuation function of the first-polarity current, and α₂(n) represents an attenuation function of the second-polarity current. The amplitude A of the first-polarity current is smaller than that of a saturation current of the magnetic lens, α₁(1)=α₂(1)=1, and 0<β<1.

### TECHNICAL FIELD

The present invention relates to a charged particle beam device and a method for demagnetizing a magnetic lens.

### BACKGROUND ART

In order to improve reproducibility of a magnetic field response or to reduce an instrumental error in a scanning electron microscope (SEM), it is required to demagnetize a magnetic lens used in the electron optical system with high accuracy.

A method for applying an amplitude-symmetrical alternating attenuation current to the magnetic lens for the purpose of demagnetizing the magnetic lens has been known. FIG. 2 shows a change in a magnetic field 200B generated in a magnetic lens when an excitation current 200I is applied to the magnetic lens. A remanent magnetization 213 exists in the magnetic lens even when the applied current is 0 (current 201), and a magnitude of the remanent magnetization 213 is denoted by Brs. In order to remove the remanent magnetization, the excitation current 200I is applied to the magnetic lens. The excitation current 200I is an amplitude-symmetrical alternating attenuation current, and positive polarity (first polarity) currents 203, 206, and 208 and negative polarity (second polarity) currents 205, 207, and 209 are alternately applied to the magnetic lens. An amplitude 202 of the positive polarity and an amplitude 204 of the negative polarity are equal to each other, and the amplitudes 202 and 204 have magnitudes equal to or larger than a saturation current of the magnetic lens. Current values of the positive polarity currents 203, 206, and 208 are reduced with the number of times of amplitude variation as indicated by an envelope curve 211, and current values of the negative polarity currents 205, 207, and 209 are reduced with the number of amplitude variations as indicated by an envelope curve 212. When the excitation current 20001 is applied, the magnetic field 200B generated in the magnetic lens is changed to the magnetic fields 213, 214, 215, 216, 217, 218, and 219, and the remanent magnetization Bre after application of the alternating attenuation current is minimized as a magnetic field 220. In this example, an example in which the positive polarity currents are applied first is shown, and negative polarity currents may be applied first.

In order to demagnetize the magnetic lens with the alternating attenuation current, the amplitude of the alternating attenuation current is required to be equal to or larger than the saturation current of the magnetic lens. FIG. 3 shows a change in a magnetic field 300B generated in the magnetic lens when an excitation current 300I is applied to the magnetic lens. Similar to the excitation current 200I, the excitation current 300I is also an amplitude-symmetrical alternating attenuation current, and is different from the excitation current 200I in that amplitudes 302 and 304 are smaller than the saturation current of the magnetic lens. In this case, due to an influence of hysteresis of the magnetic lens, a remanent magnetization Bre′ after application of the alternating attenuation current forms a magnetic field 320, and is not minimized as in the example of FIG. 2.

As described above, in order to minimize the remanent magnetization of the magnetic lens by applying the amplitude-symmetrical alternating attenuation current to the magnetic lens, a power supply that enables flowing of a large current equal to or larger than the saturation current is required, and thus cost of a device configuration is high. In PTL 1, in order to reduce a remanent magnetic flux density of the magnetic lens to 0 by the alternating attenuation current whose amplitude is smaller than that of the saturation current of the magnetic lens, a bias current for canceling out the remanent magnetization after the application of the alternating attenuation current is applied. When the case of FIG. 3 is taken as an example, a bias current that generates a magnetization (−Bre′) for canceling out the remanent magnetization Bre′ is applied to the magnetic lens.

PTL 2 discloses an E×B deflector in which a dipole field and a quadrupole field cancel each other out for a beam from one direction, and both the dipole field and the quadrupole field act on a beam from an opposite direction.

### CITATION LIST

### Patent Literature

PTL 1: JP2003-187732A

PTL 2: JP2013-239329A

### SUMMARY OF INVENTION

### Technical Problem

FIG. 4 shows a change in the magnetic field (magnetic field response) of the magnetic lens when the excitation current is changed. A magnetic field response 401 is a magnetic field response when there is no remanent magnetization, and a magnetic field response 402 is a magnetic field response when there is remanent magnetization.

In PTL 1, the remanent magnetization after the application of the alternating attenuation current is merely cancelled by the application of the bias current, and therefore, the remanent magnetization exists in the magnetic lens even if the demagnetization is performed according to the method of PTL 1. Therefore, the magnetic field response of the magnetic lens demagnetized according to the method of PTL 1 does not indicate the magnetic field response 401, but indicates the magnetic field response 402, that is, magnetic field response characteristics that differ depending on the magnitude of the residual magnetic field. The magnitude of the remanent magnetization also causes an instrumental error because the magnitude of the remanent magnetization varies for each device. In order to improve the reproducibility of the magnetic field response, it is essential to minimize the remanent magnetization when the applied current is equal to 0 to the extent that the remanent magnetization can be regarded as 0.

### Solution to Problem

A charged particle beam device according to an embodiment of the invention includes a magnetic lens, a magnetic lens controller configured to apply an excitation current to the magnetic lens, and a control unit. The control unit applies, as the excitation current, an alternating attenuation current to demagnetize the magnetic lens, the alternating attenuation current oscillating such that a current value alternately becomes a first-polarity current I₁(n) and a second-polarity current I₂(n) in which n represents the number of times of amplitude variation. The first-polarity current I₁(n) and the second-polarity current I₂(n) are expressed as

$${I}_{1} ( n ) = A \times {α}_{1} ( n )$$

$${I}_{2} ( n ) = - A \times β \times {α}_{2} ( n ) ,$$

in which oscillation of the attenuation alternating current is started from a first polarity, A represents an amplitude of the first-polarity current, β represents an asymmetric coefficient, α₁(n) represents an attenuation function of the first-polarity current, and α₂(n) represents an attenuation function of the second-polarity current. The amplitude A of the first-polarity current is smaller than that of a saturation current of the magnetic lens, α₁(1)=α₂(1)=1, and 0<β<1.

### Advantageous Effects of Invention

A magnetic lens can be demagnetized with high accuracy, and an instrumental error can be reduced. Other problems and novel features will become apparent from the description of the present specification and the accompanying drawings.

### BRIEF DESCRIPTION OF DRAWINGS

FIG. 1 is a schematic diagram of a scanning electron microscope.

FIG. 2 is a diagram showing a change in a magnetic field generated in a magnetic lens when an amplitude-symmetrical alternating attenuation current (amplitude≥saturation current) is applied to the magnetic lens.

FIG. 3 is a diagram showing a change in a magnetic field generated in the magnetic lens when an amplitude-symmetrical alternating attenuation current (amplitude<saturation current) is applied to the magnetic lens.

FIG. 4 is a diagram showing a magnetic field response of the magnetic lens when an excitation current is changed.

FIG. 5 is a diagram showing a method for demagnetizing a magnetic lens according to the present embodiment.

FIG. 6A shows an example of a waveform of an amplitude-asymmetric alternating attenuation current.

FIG. 6B shows an example of a waveform of the amplitude-asymmetric alternating attenuation current.

FIG. 6C shows an example of a waveform of the amplitude-asymmetric alternating attenuation current.

FIG. 6D shows an example of a waveform of the amplitude-asymmetric alternating attenuation current.

FIG. 7A is a diagram showing a method for determining an asymmetric coefficient β.

FIG. 7B is a diagram showing a method for determining an attenuation constant γ.

FIG. 8 is a flowchart for setting demagnetization parameters (the asymmetric coefficient g and the attenuation constant γ).

FIG. 9 is a schematic diagram of an E×B lens.

FIG. 10 is a diagram showing a problem in demagnetization of a multipole lens.

### DESCRIPTION OF EMBODIMENTS

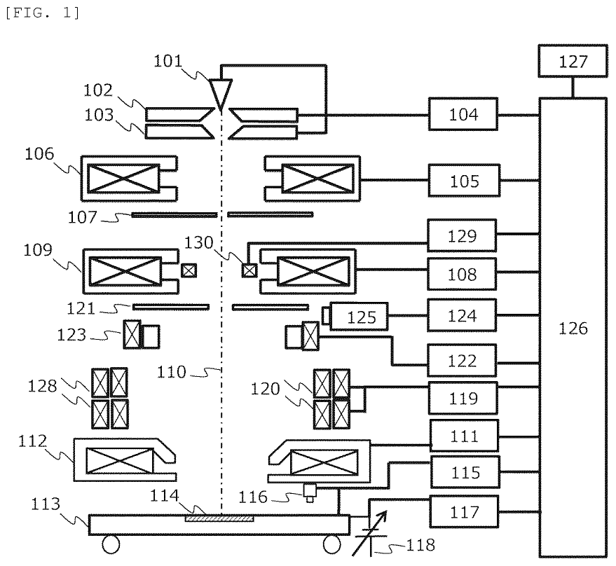

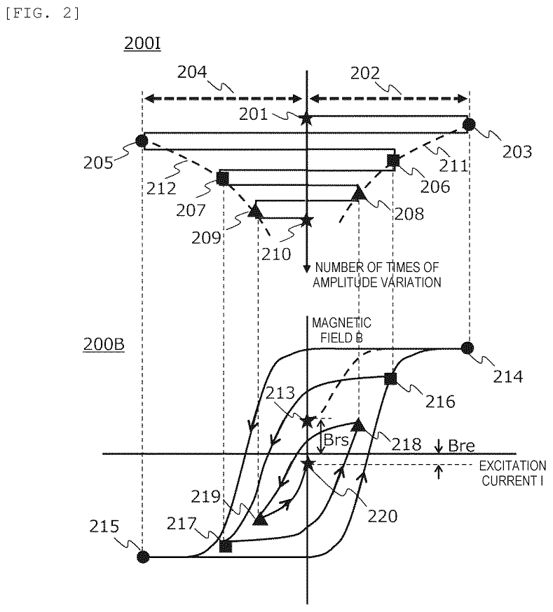

An outline of a scanning electron microscope will be described with reference to FIG. 1. A cathode 101, a first anode 102, and a second anode 103 constitute a charged particle source (electron gun), and are controlled by an electron gun control unit 104. When the electron gun control unit 104 applies an extraction voltage between the cathode 101 and the first anode 102, primary electrons are emitted from the cathode 101 at a predetermined current density. Further, the primary electrons are accelerated and emitted to a subsequent stage by an acceleration voltage applied between the cathode 101 and the second anode 103.

The emitted primary electrons are focused by a first condenser lens 106 whose excitation current is controlled by a first condenser lens control unit 105. The primary electrons focused by the first condenser lens 106 are limited to having a predetermined current amount at an opening of an objective movable aperture 107. The primary electrons passed through the objective movable aperture 107 are focused at an appropriate position on an optical axis 110 by a second condenser lens 109 whose excitation current is controlled by a second condenser lens control unit 108. The primary electrons focused by the second condenser lens 109 are focused on a sample 114 disposed on a stage 113 by an objective lens 112 whose excitation current is controlled by an objective lens control unit 111. The excitation current of the objective lens 112 is set based on a working distance measured by a sample height measuring instrument 116 controlled by a stage control unit 115.

A returning power supply 118 controlled by a returning voltage control unit 117 is connected to the stage 113. The primary electrons are decelerated by generating a voltage between the objective lens 112 and the sample 114 by the returning power supply 118.

The sample 114 is two-dimensionally scanned with the primary electrons by a scanning deflector 120 controlled by a deflector control unit 119. Secondary electrons are generated by an interaction between the primary electrons and the sample 114. The generated secondary electrons pass through the objective lens 112 and form a spread spot on a secondary electron conversion plate 121. The secondary electron conversion plate 121 is scanned with the secondary electrons by the scanning deflector 120, and tertiary electrons are generated by an interaction between the secondary electrons and the secondary electron conversion plate 121. The tertiary electrons are deflected, by an E×B lens 123 whose applied voltage and excitation current are controlled by an E×B control unit 122, toward a direction of a detector 125 controlled by a detector control unit 124, and are detected by the detector 125. The detected tertiary electrons are converted into electric signals, and the electric signals are calculated by a control unit 126 and displayed as an SEM image on a display device 127. The E×B lens 123 has a multipole structure, so that aberrations (astigmatism, chromatic aberrations, deflection distortion, and the like) generated when electrons are deflected from the optical axis 110 can also be corrected. Details will be described later.

When the field of view of the SEM image is moved, the stage 113 is moved by the stage control unit 115 or a radiation position of the primary electrons on the sample 114 is moved by an image shift deflector 128 controlled by a deflector control unit 119. An astigmatism corrector 130 controlled by an astigmatism corrector control unit 129 corrects parasitic astigmatism of the electron optical system.

The charged particle beam device of the present embodiment is not limited to the scanning electron microscope shown in FIG. 1, and may be a scanning transmission electron microscope, a transmission electron microscope, a scanning ion microscope, a focused ion beam device, or the like.

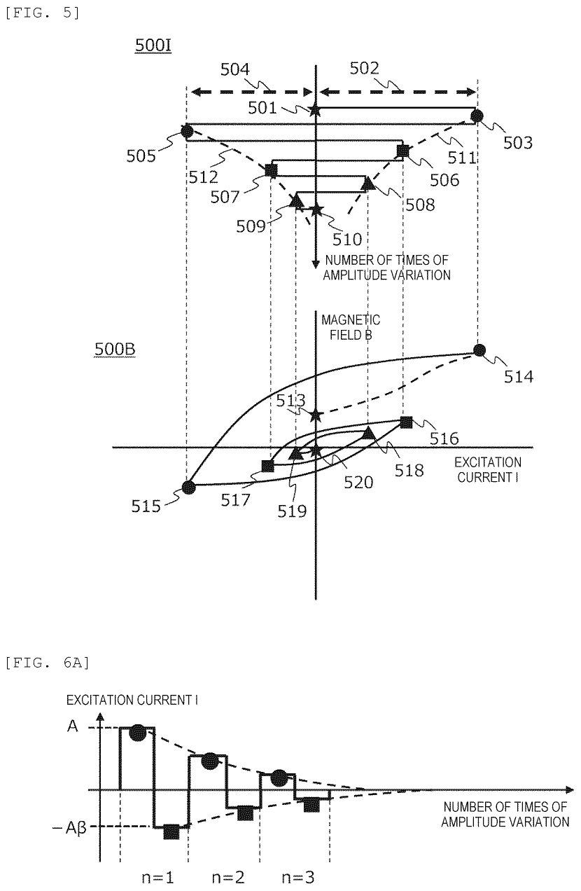

A method for demagnetizing the magnetic lens in the present embodiment will be described with reference to FIG. 5. FIG. 5 shows a change in a magnetic field 500B generated in the magnetic lens when an excitation current 500I is applied to the magnetic lens. The excitation current 500I is an alternating attenuation current, and positive polarity (first polarity) currents 503, 506, and 508 and negative polarity (second polarity) currents 505, 507, and 509 are alternately applied to the magnetic lens. In the excitation current 500I, an amplitude 502 of a positive polarity and an amplitude 504 of a negative polarity are different from each other (in this example, the amplitude 502>the amplitude 504), and the amplitudes 502 and 504 have a magnitude smaller than a saturation current of the magnetic lens. Current values of the positive polarity currents 503, 506, and 508 are reduced with the number of times of amplitude variation as indicated by an envelope curve 511, and current values of the negative polarity currents 505, 507, and 509 are reduced with the number of times of amplitude variation as indicated by an envelope curve 512. When the excitation current 500I is applied, the magnetic field 500B generated in the magnetic lens is changed to the magnetic fields 513, 514, 515, 516, 517, 518, and 519, and the remanent magnetization after the application of the alternating attenuation current is minimized as a magnetic field 520. An example in which a positive polarity current is applied first is shown here, and a negative polarity current may be applied first. The amplitudes may be asymmetric between the positive polarity and the negative polarity, and in a demagnetization process, an amplitude of a polarity current to be applied later is set based on an amplitude of a polarity current to be applied earlier.

The alternating attenuation current applied for demagnetization of the magnetic lens in the present embodiment can be formulated as follows.

The alternating attenuation current oscillates such that the current values alternately become a first-polarity current I₁(n) and a second-polarity current I₂(n) (n is the number of times of amplitude variation). The first-polarity current I₁(n) and the second-polarity current I₂(n) are respectively expressed as

$${I}_{1} ( n ) = A \times {α}_{1} ( n )$$

$${I}_{2} ( n ) = - A \times β \times {α}_{2} ( n ) ,$$

in which the oscillation is started from a first polarity, A represents the amplitude 502 of the first polarity, β represents an asymmetric coefficient, α₁(n) represents an attenuation function of the first polarity (corresponding to the envelope curve 511), and α₂(n) represents an attenuation function of the second polarity (corresponding to the envelope curve 512). Note that 0<β<1. Further, the attenuation function is a function that satisfies α₁(n)≥α₁(n+1) and α₂(n)≥α₂(n+1), in which α₁(1)=α₂(1)=1.

Note that the attenuation function α₁(n) of the first polarity and the attenuation function α₂(n) of the second polarity may be the same or different. When α₁(n) and α₂(n) are the same, the control can be simplified, and when α₁(n) and α₂(n) are different from each other, the type and magnitude of the parasitic aberration caused by the remanent magnetization can be changed.

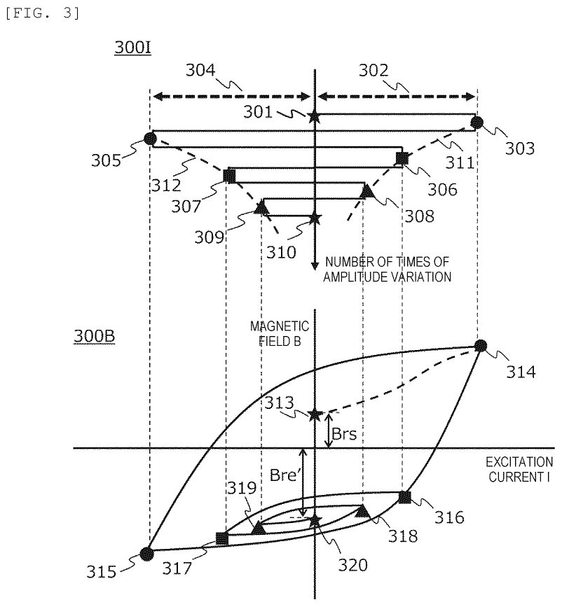

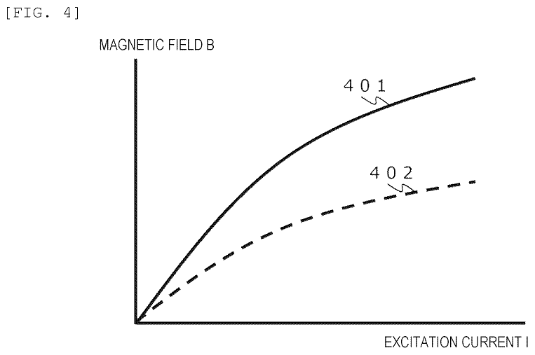

As shown in FIG. 3, when the amplitude is set to be smaller than the saturation current while maintaining the amplitude-symmetrical alternating attenuation current, a value of the remanent magnetization converges as the number of times of amplitude variation n increases. However, the value of the remanent magnetization converges to Bre′ that is a value different from 0. In the present embodiment, by providing a degree of freedom to the amplitude of the alternating attenuation current, that is, by making the amplitudes of the alternating attenuation current asymmetric, a convergence destination of the remanent magnetization can be adjusted to 0. The remanent magnetization can be minimized to a value, which can be regarded as 0, by setting an appropriate β.

In addition, it is desirable to define an attenuation constant γ indicating the degree of amplitude attenuation, and set the attenuation function of the first polarity to α₁(n, γ) and the attenuation function of the second polarity to α₂(n, γ). The attenuation constant is a constant for controlling an attenuation amount of the current value per amplitude variation, that is, a magnitude of a difference between α₁(n) and α₁(n+1) and a difference between α₂(n) and α₂(n+1). As the current value of the alternating attenuation current is rapidly reduced, the demagnetization time can be shortened. On the other hand, as the attenuation amount per oscillation variation is smaller, the difference between the remanent magnetization after the application of the alternating attenuation current and 0 can be controlled to be smaller.

For example, the attenuation function α(n, γ) may be any one of a linear function, an exponential function, and a power attenuation function. When the attenuation function is a linear function, the attenuation function can be expressed as α(n, γ)=−γ×n+1 (0<γ<1). When the attenuation function is an exponential function, the attenuation function can be expressed as α(n, γ)=exp(−γ n) (0<γ<1). When the attenuation function is a power attenuation function, the attenuation function can be expressed as α(n, γ)=(1/γ)ⁿ (γ>1).

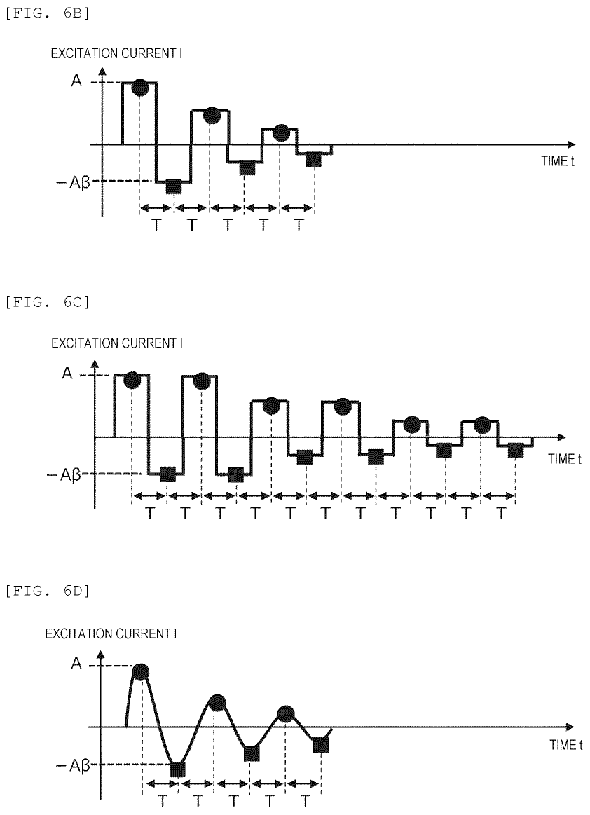

Examples of waveforms of the amplitude asymmetric alternating attenuation current are shown in FIGS. 6A to 6D.

### (1) FIG. 6A

FIG. 6A shows the alternating attenuation current shown in FIG. 5. In the case of the number of times of amplitude variation n=1, a current (I₁(1)) having a current value A is applied, and then a current (I₂(1)) having a current value −Aβ is applied. Subsequently, in the case of the number of times of amplitude variation n=2, a current (I₁(2)) having a current value A α₁(2) is applied, and then a current (I₂(2)) having a current value −Aβ α₂(2) is applied. After this processing is repeated a predetermined number of times of oscillation variations, the applied current is 0.

### (2) FIG. 6B

FIG. 6B shows an alternating attenuation current waveform having a horizontal axis as a time axis, and the waveform has a current value that alternately becomes a first-polarity current I₁(n) and a second-polarity current I₂(n) with a predetermined time interval T. Accordingly, the excitation current applied to the magnetic lens can be driven for a period of time.

### (3) FIG. 6C

FIG. 6C shows a waveform in which the current values are equal to each other over k times of amplitude variation (two times in FIG. 6C). An excitation path is magnetically memorized by oscillating a plurality of times, so that the reproducibility of the magnetic field response can be improved.

### (4) FIG. 6D

FIG. 6D shows an example in which the waveform is a sine wave. When the waveform is a sine wave, the rising time and falling time of the excitation current become gentle, and power supply fluctuation such as overshoot and ringing can be prevented. Accordingly, the magnetic field response following the power supply fluctuation is prevented, and the reproducibility of the magnetic field response can be improved. Here, the waveform is not limited to the sine wave, and may be a trapezoidal wave, a triangular wave, or the like as long as the rising time and the falling time of the excitation current are delayed.

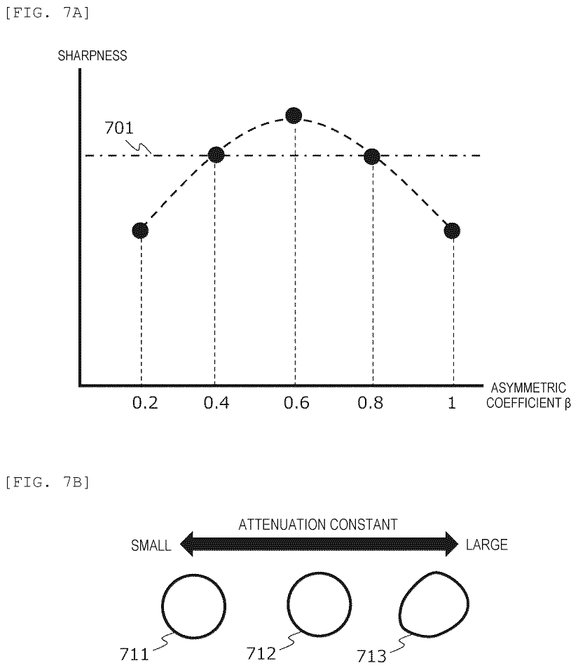

A method for determining the asymmetric coefficient β will be described with reference to FIG. 7A. The magnitude of the remanent magnetization after the application of the alternating attenuation current can be adjusted according to the magnitude of the asymmetric coefficient β. The remanent magnetization of the magnetic lens cannot be measured, and thus an appropriate asymmetric coefficient β is set based on sharpness of an observation image obtained by the scanning electron microscope. Although the asymmetric coefficient β varies depending on a material and structure of the magnetic lens, the observation image deteriorates, that is, the sharpness is lowered as the remanent magnetization is increased. The sharpness enough to capture characteristics of a straight line or a curve in the observation image is set as a threshold value 701 of the sharpness, and β exceeding the threshold value 701 is selected. In the example of FIG. 7A, 0.4<β<0.8 may be satisfied. The sharpness can be calculated by applying a sharpness evaluation filter (differential, second-order differential, Sobel, Laplacian, Fourier transform, or the like) to the observation image to create a sharpness evaluation image. The sharpness for each direction may be calculated and used as the evaluation value.

A method for determining the attenuation constant γ will be described with reference to FIG. 7B. The adjustment of the asymmetric coefficient β is performed to roughly adjust the magnitude of the remanent magnetization, whereas the adjustment of the attenuation constant γ is performed to finely adjust the magnitude of the remanent magnetization. In the adjustment, a shape of an electron beam after the application of the alternating attenuation current is measured, and the largest value of the attenuation constant γ at which the shape of the electron beam is a perfect circle is selected as the attenuation constant γ. This is because the time required for demagnetization is shortened as the attenuation constant γ is increased. In the case of FIG. 7B, the attenuation constant γ that gives the beam shape 712 may be selected.

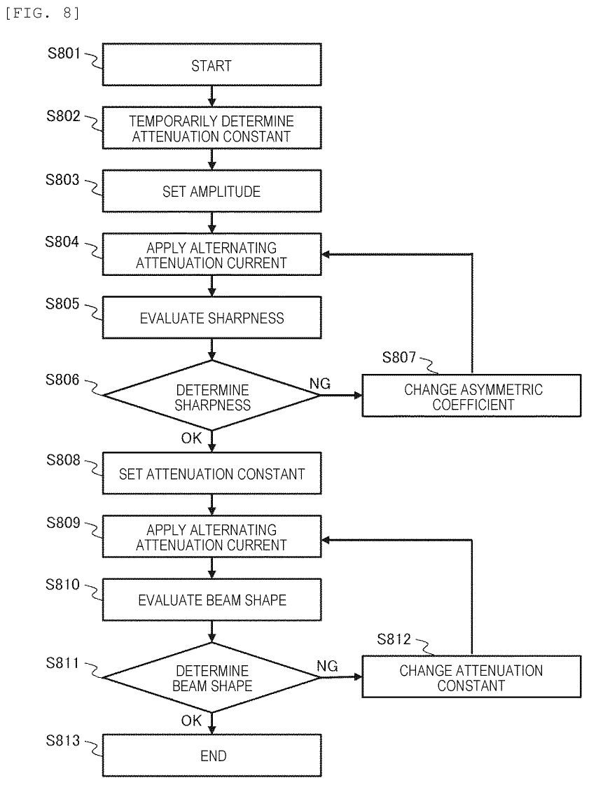

FIG. 8 is a flowchart for setting demagnetization parameters (the asymmetric coefficient R and the attenuation constant γ). First, the attenuation constant γ is temporarily determined (S802). At this stage, a large attenuation constant γ is set. Next, the amplitude A and the asymmetric coefficient β are set (S803). As the amplitude A, a current value larger than a current amount during actual use (observation) of the magnetic lens is set. The asymmetric coefficient β is temporarily determined. After the alternating attenuation current oscillating between the first-polarity current I₁(n) and the second-polarity current I₂(n) based on the above temporarily determined demagnetization parameters is applied to the magnetic lens (S804), an observation image is obtained. As shown in FIG. 7A, the sharpness of the observation image is evaluated (S805), and whether the sharpness exceeds a threshold value is determined (S806). If the sharpness does not exceed the threshold value, the asymmetric coefficient β is changed, and the processing returns to step S804 again. If the sharpness exceeds the threshold value, the asymmetric coefficient β is determined, and the processing proceeds to S808.

Subsequently, an attenuation constant is set (S808). After an alternating attenuation current oscillating between the first-polarity current I₁(n) and the second-polarity current I₂(n) based on the determined asymmetric coefficient β and the attenuation constant γ temporarily determined in step S808 is applied to the magnetic lens (S809), a shape of an electron beam is evaluated (S810). The beam shape is determined (S811), the attenuation constant γ is changed to be small if the beam shape is not a perfect circle, and the attenuation constant γ is changed to be large if the beam shape is a perfect circle (S812), and the processing of steps S809 to S811 is repeated. The largest attenuation constant at which the beam shape is a perfect circle is determined as the attenuation constant γ. The determined demagnetization parameters and attenuation function are stored in a storage device (memory) of the control unit 126 for each magnetic lens, and the setting flow is terminated (S813). When the magnetic lens is demagnetized, the demagnetization parameters and the attenuation function stored in the storage device are read, and the magnetic lens is demagnetized.

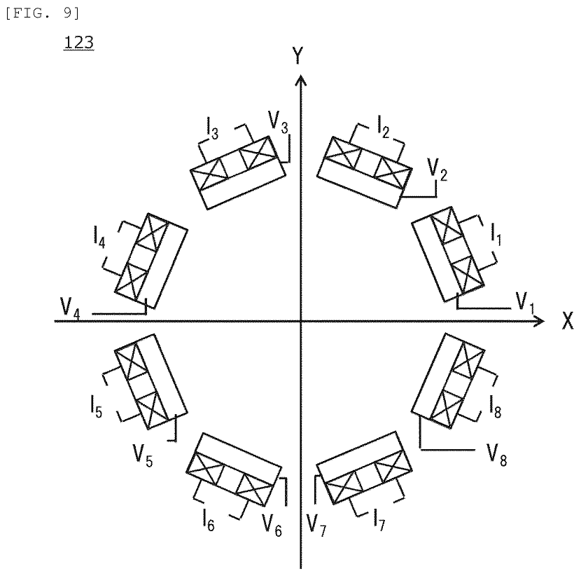

An example in which the method for demagnetizing the magnetic lens according to the present embodiment is performed on the E×B lens 123 will be described. The E×B lens 123 has a structure disclosed in PTL 2, and an outline of the E×B lens 123 will be described with reference to FIG. 9. The E×B lens 123 includes, for example, electric field deflectors that are eight poles (corresponding to V₁ to V₈) and magnetic field deflectors that are eight poles (corresponding to I₁ to I₈). The lens thus divided into a plurality of pieces in a plane is referred to as a multipole lens. The E×B lens is not limited to the 8-pole lens, and can be applied to a multipole lens such as a quadrupole lens, a 6-pole lens, a 10-pole lens, or a 12-pole lens. The E×B lens 123 can generate a predetermined multipole field by applying an electric field or an excitation current of each pole at a predetermined ratio. Examples of the multipole field include a dipole field, a quadrupole field, a hexapole field, and an octupole field. The E×B lens 123 has a function of deflecting signal electrons from the optical axis 110 toward a direction of the detector 125 using a dipole field and a function of correcting aberrations (astigmatism, chromatic aberrations, deflection distortion, and the like) generated when electrons are deflected from the optical axis 110. An output method and an aberration correction method of a multipole field are described in PTL

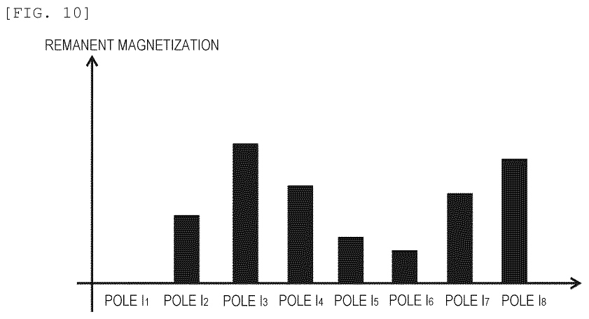

As described above, since the magnetic field deflectors (poles) of the E×B lens have different magnetic characteristics, non-uniform remanent magnetization occurs in the plane when the respective magnetic field deflectors are demagnetized by the same demagnetization method. The remanent magnetization varies for each apparatus, which causes an instrumental error. For example, FIG. 10 shows remanent magnetization when the demagnetization method optimum for the pole I₁ is applied to all the poles of the E×B lens. In this way, when different remanent magnetization is generated for each pole, parasitic aberrations such as coma aberrations is generated. Therefore, the decomposition ability deteriorates, and the degree of deterioration is also different for each device, which causes an instrumental error.

The multipole lens has non-uniform magnetic characteristics in the plane, and thus it is difficult to minimize the remanent magnetization of all the poles. Therefore, it is effective to prevent the occurrence of the parasitic aberrations that are likely to affect the decomposition performance. For example, when the demagnetization method in the present embodiment is applied to a pole that generates a quadrupole field, an oblique quadrupole field, or a pole field obtained by superimposing a quadrupole field and an oblique quadrupole field, and generates a quadrupole lens that prevents astigmatism for each direction, deterioration of the decomposition ability caused by remanent magnetization can be significantly prevented. A general demagnetization method is applied to a pole other than the pole that generates a quadrupole field, an oblique quadrupole field, or a pole field obtained by superimposing a quadrupole field and an oblique quadrupole field.

### REFERENCE SIGNS LIST

101: cathode
102: first anode
103: second anode
104: electron gun control unit
105, 108: condenser lens control unit
106, 109: condenser lens
107: objective movable aperture
110: optical axis
111: objective lens control unit
112: objective lens
113: stage
114: sample
115: stage control unit
116: sample height measuring instrument
117: returning voltage control unit
118: returning power supply
119: deflector control unit
120: scanning deflector
121: secondary electron conversion plate
122: E×B control unit
123: E×B lens
124: detector control unit
125: detector
126: control unit
127: display device
128: image shift deflector
129: astigmatism corrector control unit
130: astigmatism corrector
200I, 300I, 500I: excitation current
200B, 300B, 500B: magnetic field
202, 204, 302, 304, 502, 504: amplitude
203, 206, 208, 303, 306, 308, 503, 506, 508: first-polarity current
205, 207, 209, 305, 307, 309, 505, 507, 509: second-polarity current
211, 212, 311, 312, 511, 512: envelope curve
213, 220, 313, 320, 513, 520: remanent magnetization
214, 215, 216, 217, 218, 219, 314, 315, 316, 317, 318, 319, 514, 515, 516, 517, 518, 519: magnetic field
401, 402: magnetic field response
701: threshold value
711, 712, 713: beam shape

1. A charged particle beam device comprising:
a magnetic lens;
a magnetic lens controller configured to apply an excitation current to the magnetic lens; and
a control unit, wherein
the control unit applies, as the excitation current, an alternating attenuation current to demagnetize the magnetic lens, the alternating attenuation current oscillating such that a current value alternately becomes a first-polarity current I₁(n) and a second-polarity current I₂(n) in which n represents the number of times of amplitude variation,
the first-polarity current I₁(n) and the second-polarity current I₂(n) are expressed as
$${I}_{1} ( n ) = A \times {α}_{1} ( n )$$
$${I}_{2} ( n ) = - A \times β \times {α}_{2} ( n ) ,$$
in which oscillation of the attenuation alternating current is started from a first polarity, A represents an amplitude of the first-polarity current, β represents an asymmetric coefficient, α₁(n) represents an attenuation function of the first-polarity current, and α₂(n) represents an attenuation function of the second-polarity current,
the amplitude A of the first-polarity current is smaller than that of a saturation current of the magnetic lens, α₁(1)=α₂(1)=1, and 0<β<1.

2. The charged particle beam device according to claim 1, wherein
the alternating attenuation current has a current value that alternately becomes the first-polarity current I₁(n) and the second-polarity current I₂(n) at a predetermined time interval.

3. The charged particle beam device according to claim 1, wherein
the asymmetric coefficient β is set based on sharpness of an observation image obtained after the application of the alternating attenuation current to the magnetic lens.

4. The charged particle beam device according to claim 1, wherein
the attenuation function of the first-polarity current and the attenuation function of the second-polarity current are expressed as
α₁(n)=α₁(n,γ)
α₂(n)=α₂(n,γ)
in which γ represents an attenuation constant, and
the attenuation functions are any one of a linear function, an exponential function, or a power attenuation function.

5. The charged particle beam device according to claim 4, wherein
the attenuation constant γ is set such that a beam shape of a charged particle beam after the application of the alternating attenuation current to the magnetic lens is a perfect circle.

6. The charged particle beam device according to claim 5, wherein
the asymmetric coefficient β is set based on sharpness of an observation image obtained after the application of the alternating attenuation current whose attenuation constant γ is temporarily determined to the magnetic lens, and
the attenuation constant γ is set such that the beam shape of the charged particle beam after the application of the alternating attenuation current whose asymmetric coefficient β is set to the magnetic lens is a perfect circle.

7. The charged particle beam device according to claim 6, wherein
the control unit includes a storage device configured to store the set asymmetric coefficient β, the set attenuation constant γ, the set attenuation function α₁(n, γ) of the first-polarity current, and the set attenuation function α₂(n, γ) of the second-polarity current.

8. The charged particle beam device according to claim 1, wherein
the attenuation function α₁(n) of the first-polarity current is equal to the attenuation function α₂(n) of the second-polarity current.

9. The charged particle beam device according to claim 1, wherein
the magnetic lens is a multipole lens, and
the control unit applies the alternating attenuation current to a pole, in the multipole lens, which generates a quadrupole field, an oblique quadrupole field, or a pole field obtained by superimposing a quadrupole field and an oblique quadrupole field.

10. A method for demagnetizing a magnetic lens, the method comprising:
applying, as an excitation current, an alternating attenuation current to demagnetize the magnetic lens, the alternating attenuation current oscillating such that a current value alternately becomes a first-polarity current I₁(n) and a second-polarity current I₂(n) in which n represents the number of times of amplitude variation, wherein
the first-polarity current I₁(n) and the second-polarity current I₂(n) are expressed as
$${I}_{1} ( n ) = A \times {α}_{1} ( n )$$
$${I}_{2} ( n ) = - A \times β \times {α}_{2} ( n ) ,$$
in which oscillation of the attenuation alternating current is started from a first polarity, A represents an amplitude of the first-polarity current, β represents an asymmetric coefficient, α₁(n) represents an attenuation function of the first-polarity current, and α₂(n) represents an attenuation function of the second-polarity current,
the amplitude A of the first-polarity current is smaller than a saturation current of the magnetic lens, α₁(1)=α₂(1)=1, and 0<β<1.
